(19) United States
(12) Patent Application Publication
(10) Pub. No.: US 2009/0071406 A1
(43) Pub. Date: Mar. 19, 2009

(54) COOLED BACKING PLATE

(76) Inventors: SOO YOUNG CHOI, Fremont, CA (US); Robin L. Tiner, Santa Cruz, CA (US); John M. White, Hayward, CA (US)

Correspondence Address: Applied Materials, Inc.;c/o Fulbright & Jaworski L.L.P., Attn: Billy A. Robbins, 555 South Flower Street, Forty-First Floor, Los Angeles, CA, 90071, US

(21) Appl. No.: 11/858,020

(22) Filed: Sep. 19, 2007

(51) Int. Cl. C23C 16/00

(52) U.S. Cl. 118/724

(57) ABSTRACT

A plasma enhanced chemical vapor deposition chamber (PECVD) which includes a backing plate that provides support to a diffuser. The backing plate includes a plurality of fluid conduits adapted for circulation of a cooling fluid therethrough to remove excess heat generated in the chamber by the plasma to thereby maintain the backing plate in a stable condition thereby maintaining the diffuser in a stable position during the deposition of material from the plasma.

### BACKGROUND OF THE INVENTION

1. Field of the Invention

The present invention relates generally to a plasma enhanced chemical vapor deposition chamber and more specifically to controlling the temperature within the chamber during deposition of semiconductor materials on a suitable substrate to form photovoltaic cells.

2. Description of the Related Art

Plasma enhanced chemical vapor deposition (PECVD) chambers for the deposition of semiconductor materials on substrates is well known in the art. Examples of such PECVD chambers are shown in U.S. Pat. No. 6,477,980 and published Patent Application US 2006/0060138 A1 each of which is incorporated herein by this reference. Plasma processes includes supplying a processed gas mixture to a vacuum chamber called a plasma chamber and then applying electromagnetic power to excite the process gas to a plasma state. The plasma decomposes the gas mixture into ion species that perform the desired deposition on an appropriate substrate.

In capacitively excited chemical vapor deposition chambers the plasma is excited by RF power applied between an anode electrode and a cathode electrode. Generally the substrate is mounted on a pedestal or susceptor that functions as a cathode electrode and the anode electrode is mounted a short distance from and generally parallel to the substrate. Commonly the anode electrode also functions as a gas distribution plate or diffuser for supplying the process gas mixture into the chamber. The diffuser is perforated with a plurality of orifices through which the process gas mixture flows into the gap between the anode and the cathode. The orifices are spaced across the surface of the diffuser to maximize the spatial uniformity of the process gas mixture adjacent the substrate.

It is important that the space between the surface of the diffuser and the surface of the substrate be uniformly maintained to assure proper deposition of the materials on the substrate. If a diffuser is warped or sags during the deposition process the process may not produce the desired uniform deposition. During PECVD the temperatures within the chamber are on the order of 300° to 450° C. or higher and can deform the diffuser particularly when large area substrates on the order of 2200 mm by 2600 mm are utilized. To stabilize the diffuser there has been provided a central support member extending between a backing plate and the diffuser. The backing plate is relatively thicker in cross section than the diffuser and thus provides a substantially static support. In addition, to the central support member or alternatively thereto, the backing plate may be provided with a plurality of bores formed surrounding the center area with each of the bores adapted to receive a threaded support that is configured to mate with a corresponding mating portion in the diffuser. These supports have been found to be quite successful if the duration of the plasma is limited. However, when relatively thick layers of semiconductor material are deposited in a PECVD chamber, such as is required to form the intrinsic layer of a photovoltaic cell, at the elevated temperatures generated in the plasma it has been found that the backing plate may itself sag, warp or otherwise become non-stable which in turn causes the diffuser to move thereby destroying the uniformity of the separation between the surface of the diffuser and the substrate.

There is therefore a need to provide a means for stabilizing the backing plate to assure the uniformity of deposition of materials from the plasma onto the surface of the substrate.

### SUMMARY OF THE INVENTION

The invention generally relates to a plasma enhanced chemical vapor deposition chamber for depositing amorphous or microcrystalline silicon on a glass substrate to fabricate solar voltaic cells which chamber includes a backing plate having at least one fluid receiving conduit to receive cooling fluid to remove heat generated within the chamber by the plasma which conduit defines an input port for injecting fluid into the conduit and an output port for removing fluid from the conduit.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a side view in cross section of a plasma enhanced chemical vapor deposition chamber constructed in accordance with the principles of the present invention;

FIG. 2 is a cross-section of a portion of a plasma enhanced chemical vapor deposition chamber illustrating another embodiment of such a structure;

FIG. 3 is a top view of a backing plate constructed in accordance with the principles of the present invention;

FIG. 4 is a cross-sectional view taken about the lines 4-4 of FIG. 3; and

FIG. 5 is a schematic illustration of an alternative embodiment of a structure for cooling a backing plate constructed in accordance with another embodiment of the present invention.

FIG. 6 is a partial cross sectional schematic illustration of a further embodiment of the present invention; and

FIG. 7 is a partial cross sectional schematic illustration of yet another alternative embodiment of a structure constructed in accordance with the present invention.

### DETAILED DESCRIPTION

The embodiments of the present invention generally provide a plasma enhanced chemical vapor deposition chamber in which the backing plate is utilized to support the diffuser and in which the backing plate is constructed to have at least one fluid conduit in thermal transfer contact therewith. A fluid is circulated through the conduit and has a lower temperature upon being introduced into the conduit than when being removed from the conduits thereby removing heat from the backing plate which was generated by the plasma during the deposition process. Through removal of heat from the backing plate, the backing plate is rendered more stable and in turn keeps the diffuser in proper alignment with respect to the substrate so that the material deposited on the substrate as a result of the plasma reaction is uniform.

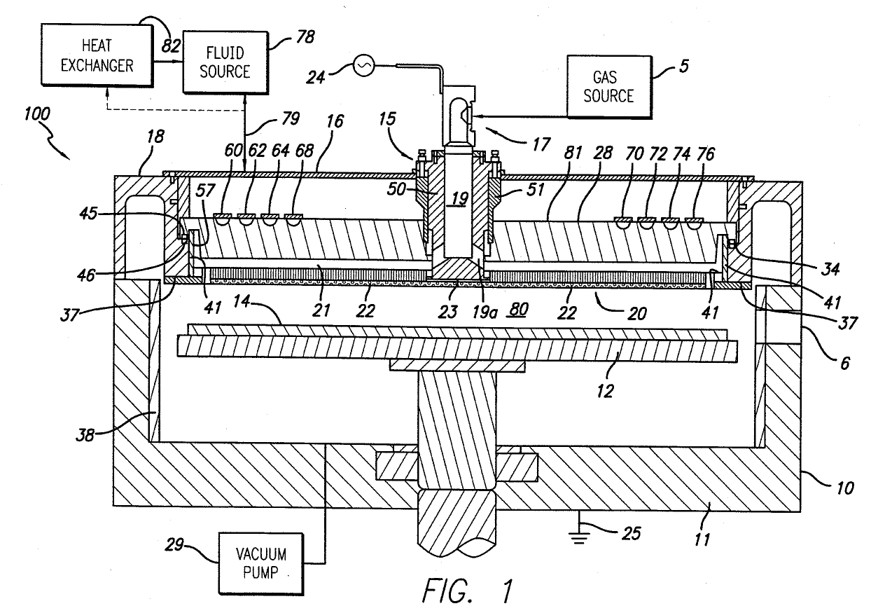

FIG. 1 is a side view in cross section of a chamber 100 that is suitable for plasma enhanced chemical vapor deposition (PECVD) processes for fabricating various devices on a large area glass substrate. The chamber 100 is configured to form structures and devices on a large area substrate for use in the fabrication of photovoltaic cells for solar cell arrays. The present invention is particularly useful in forming the P-I-N structures of amorphous or polycrystalline silicon for use in photovoltaic cells or tandem photovoltaic cells.

The chamber 100 consists of a chamber sidewall 10, a bottom 11, a substrate support 12, such as a susceptor, which supports a large area substrate 14. The chamber 100 also has a port 6, such as a slit valve, that facilitates transfer of the large area substrate by selectively opening and closing. The chamber 100 also includes a lid having an exhaust channel 18 surrounding a gas inlet manifold that consists of a cover plate 16, a first plate, such as a backing plate 28, and a second plate, such as a gas distribution plate, for example, a diffuser 20. The diffuser 20 may be any substantially planar solid that is adapted to provide a plurality of passages for a process gas or gasses from a gas source 5 coupled to the chamber 100. The diffuser 20 is positioned above the substrate 14 and suspended vertically by at least one support member, which in this embodiment is a diffuser gravitational support 15. In this embodiment, the diffuser 20 is also supported from an upper lip 55 of the exhaust channel 18 by a flexible suspension 57. A flexible suspension is disclosed in detail by U.S. Pat. No. 6,477,980, which issued Nov. 12, 2002 with the title “Flexibly Suspended Gas Distribution Manifold for a Plasma Chamber” and is incorporated by reference herein to the extent the reference is not inconsistent with this specification. The flexible suspension 57 is adapted to support the diffuser 20 from its edges and to allow expansion and contraction of the diffuser 20. Other edge suspensions of the diffuser 20 may be used with the diffuser gravitational support 15, and the diffuser support 15 may be used without edge suspension. For example, the diffuser 20 may be supported at its perimeter with supports that are not flexible, or may be unsupported at the edge. The diffuser gravitational support 15 may be coupled to the gas source 5 which supplies a process gas to a gas block 17 mounted on the support 15. The gas block 17 is in communication with the diffuser 20 via a longitudinal bore 19, within the support 15, and supplies a process gas to a plurality of orifices 22 within the diffuser 20.

The diffuser gravitational support 15 is a substantially symmetrical body that is coupled to the backing plate 28. The backing plate 28 is a substantially planar plate having a suitable bore through in a center area for receiving the diffuser gravitational support 15, and is supported on its perimeter by the exhaust channel 18. The backing plate 28 is sealed on its perimeter by suitable O-rings 45 and 46 at points where the plate 28 and the exhaust channel 18 join, which protect the interior of chamber 100 from ambient environment and prevent escape of process gases. The diffuser gravitational support 15 extends upwardly from the backing plate 28, through a suitable bore in the cover 16. In this embodiment, the gravitational support 15, with the diffuser 20 attached, is adapted to remain substantially static in its position above the large area substrate 14 and substrate support 12, while the substrate support 12 is adapted to raise and lower the substrate 14 to and from a transfer and processing position.

In operation, process gases are flowed from the gas source 5 while the chamber 100 has been pumped down to a suitable pressure by a vacuum pump 29. One or more process gases travel through the gas block 17, through the longitudinal bore 19, through angled bores 19a, and are deposited in a large plenum 21 created between backing plate 28 and diffuser 20, and a small plenum 23 within the diffuser 20. The one or more process gasses then travel from the large plenum 21 and the small plenum 23 through the plurality of orifices 22 within the diffuser 20 to create a processing region 80 in an area below the diffuser 20. In operation, the large area substrate 14 is raised to this processing region 80 and the plasma excited gas or gases are deposited thereon to form structures on the large area substrate 14. A plasma may be formed in the processing region 80 by a plasma source 24 coupled to the chamber 100. The plasma source 24 is preferably a radio frequency (RF) power source. The RF power source may be inductively or capacitively coupled to the chamber 100. Although the plasma source 24 is shown coupled to the gravitational support 15 in this embodiment, the plasma source 24 may be coupled to other portions of the chamber 100.

The diffuser 20 is made of or coated with an electrically conductive material so that it may function as an electrode within the chamber 100 and the substrate support 12 may be connected to a ground 25 so it may function as an electrode in the chamber 100 as well. The materials chosen for the diffuser 20 may include steel, titanium, aluminum, or combinations thereof and the surfaces may be polished or anodized. The substrate support may further be heated by an integral heater, such as heating coils or a resistive heater coupled to or disposed within the substrate support 12. The diffuser 20 may be made of one or more pieces joined together and adapted to deliver a process gas and is electrically insulated from the chamber exhaust channel 18 and the wall 10 by dielectric spacers 34, 35, 37, 38, and 41.

Even though the backing plate 28 is relatively massive, because of the elevated temperature created by the plasma generated within the chamber as well as the long period of time during which the plasma must be maintained to deposit the relatively thick intrinsic region the temperature of the backing plate 28 becomes elevated and can reach levels such that the backing plate would begin to warp or sag particularly at the center section thereof. Such sagging would cause the diffuser 20 to also sag thereby generating a condition in which the diffuser is no longer registered properly with the substrate 14 thus causing uniformity of the material deposited thereon to be disturbed. To preclude such sagging a plurality of fluid conduits 60 through 76 are disposed in the upper surface 29 of the backing plate 28. Each of these conduits 60 through 76 are in thermal transfer contact with the backing plate 28. The conduits are connected to a fluid source 78 and fluid from the source 78 is transferred therefrom to the conduits 60 through 76 and from the conduits back to the fluid source as is indicated by the connection 79. The conduits may take any form desired in that they may be parallel and pass fluid from the source 78 and return the fluid to the source 78 or in accordance with a different embodiment the conduits 60 through 76 may in fact be a single conduit which passes along the surface 81 in a serpentine or tortuous fashion with the representations shown at 60 through 76 being sections of a single conduit.

Depending upon the content of the fluid source 78 a heat exchanger 82 may be employed and coupled to the connector 79 as illustrated to thereby pass the fluid which has traversed the backing plate 28 to remove heat therefrom through the heat exchanger 82 before it is returned to the fluid source 78. It should be understood by those skilled in the art that the utilization of the heat exchanger 82 will typically only be utilized when the fluid is a gas which is expensive and cannot be expelled to the atmosphere or is a liquid. Further discussion and illustration of the conduits and the removal of the heat accumulated by the backing plate will be provided below.

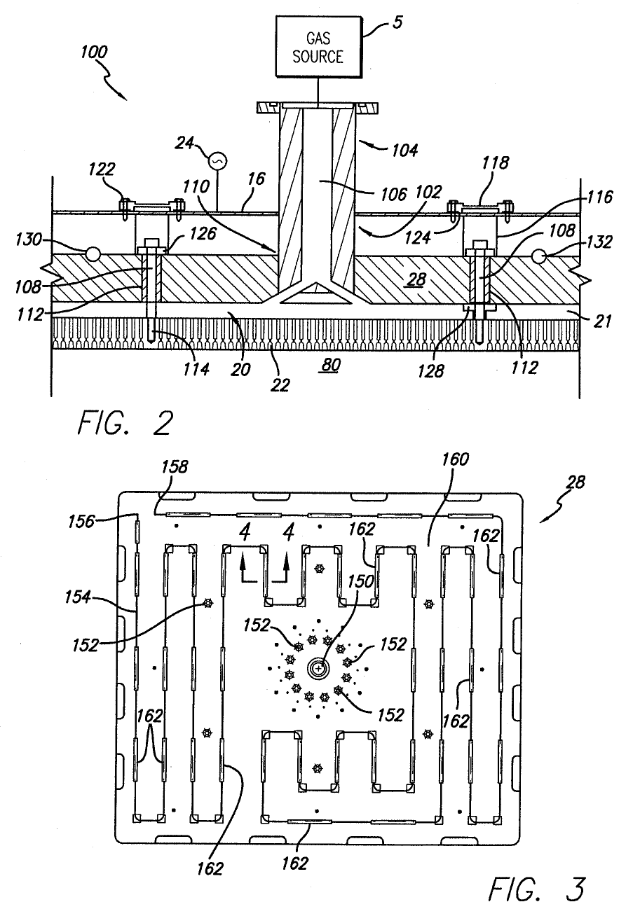

An alternative embodiment of a PECVD chamber is shown in FIG. 2. FIG. 2 is a partial schematic side view of a diffuser 20 within a chamber 100. The chamber has a cover 16 with at least one opening 102 in a center area that is adapted to receive a gas delivery assembly 104. The gas delivery assembly 104 is configured to receive a process gas or gasses from a gas source 5 and deliver the process gas to a large plenum 21 through a bore 106. The process gas may then travel through the plurality of orifices 22 in the diffuser 20 to a processing region 80. As in other embodiments, the diffuser 20 is adapted to couple to a plasma source 24 to enable a plasma in the processing region 80.

The chamber 100 has a plurality of threaded supports 108, such as bolts that extend through a first plate, such as a backing plate 28, to a second plate, such as the diffuser 20. The gas delivery assembly 104 may be integral to the backing plate 28 or the backing plate 28 may be adapted to receive the gas delivery assembly 104 through a bore-through 110 in the backing plate 28. The threaded supports 108 may be fabricated from a material and that exhibits high tensile strength and resists reaction with process chemistry such as stainless steel, titanium aluminum, or combinations thereof. The threaded supports 108 may be made of any of the above materials and may further be coated with a process resistant coating such as aluminum. The backing plate 28 has a plurality of apertures 112 formed therethrough in the center area. Each of the threaded supports 108 is threaded and a portion of the threads are adapted to be received by a mating portion, such as female threads 114, in the diffuser 20 that corresponds with the plurality of apertures 112 in the backing plate 28. The female threads are disposed in a suitable bore that does not interfere with the plurality of orifices 22 in the diffuser plate 20. Also shown is a tubular partition 116 and cap plate 118 that covers each tubular partition 116. The cap plate 118 enables access to the threaded supports 108 and together with the tubular partition 116 provides a seal from ambient environment. The cap plate 118 may be sealed by any known method, such as a clamp 120 over the cap plate 118 and fastened by screws 122 to the cover 16, with an O ring 124 therebetween. It is to be noted that the gas delivery assembly 104 in this embodiment is adapted to be static in its position in the chamber 100, and sealed from ambient atmosphere by any known methods.

In operation, the threaded supports 108 are inserted in the tubular partitions 116 through the apertures 112, and engaged to the respective female threads 114 in the diffuser 20. The threaded supports 108 are rotated to adjust the planar orientation of the diffuser 20. In this embodiment, the center area of the diffuser 20 is limited in vertical movement by the backing plate 28, which is designed to exhibit a much higher tolerance to forces such as gravity, vacuum, and heat. The backing plate 28 may yield to these forces, but not to the degree that may be experienced by the diffuser 20. In this fashion, the diffuser 20 may exhibit a deformation caused by the aforementioned forces, but the deformation is effectively tolled by the backing plate 28. It is also contemplated that the force parameters may be predetermined and any known deformation in the backing plate 28 and the diffuser 20 may be counteracted by the adjustment of the threaded supports 108. The diffuser 20 may be adjusted to allow partial deformation, but the allowed deformation is stopped at a predetermined point when the threaded supports 108 reach a mechanical limit, such as contacting a stop, which in this example is a washer 126. The threaded supports 108 are coupled between the diffuser 20 and backing plate 28. The backing plate 28 is relatively thicker in cross-section than the diffuser 20, thus providing a substantially static support point. The diffuser 20 is more malleable relative the backing plate 28 due to relative thickness and the perforations in the diffuser 20 which allows adjustment of the diffuser profile by adjusting the length of the threaded supports 108.

In another aspect, at least one adjustment member 128, such as a spacer may be used to maintain a static distance between the diffuser 20 and the backing plate 28, thereby using the threaded supports 108 to lock the adjustment member 128 in place. In this embodiment, the diffuser 20 may be formed to exhibit a desired horizontal profile by varying a thickness of the at least one adjustment member 128. The at least one adjustment member 128 may be thicker to form a convex horizontal profile to the center portion of the diffuser 20 when installed, or thinner to form a concave horizontal profile. The threaded supports 108 may then be rotated into the female threads 114 to lock the adjustment members 128 in place. Although only one adjustment member 128 is shown, the invention is not limited to this and any number of adjustment members 128 may be used, for example, each threaded support 108 may have an adjustment member coupled thereto. When the adjustment members 128 are used, the vertical movement of the diffuser 20 is limited to any movement of the backing plate 28 when reacting to forces such as heat, pressure, and gravity.

It has, however, been found that the heat generated by the sustained plasma in the processing region 80 will cause undesired movement of the backing plate 28 even with the additional supports 108 along with the adjustments and spacers as above described. Therefore, even with the configuration as shown in FIG. 2, fluid conduits, such as shown, at 130 and 132 are provided through which a cooling fluid from a source thereof may be circulated in a manner as above described with respect to FIG. 1. The circulation of the cooling fluid such as a liquid or a gas through the conduits 130 and 132 will remove the excess heat from the backing plate 28 thus allowing it to maintain a stable position so that the diffuser maintains the desired horizontal profile established by utilization of the adjusting members 128. As above indicated, the fluid conduits 130 and 132 may take any form desired such as being parallel conduits or may be a single serial conduit forming a serpentine or tortuous path along the upper surface backing plate 28. As is shown in FIG. 2, the conduit 130 and 132 may be a tube which is disposed within a groove formed in the upper surface of the backing plate 28 with the tube being in thermal transfer contact with the backing plate 28.

Referring now to FIG. 3 there is shown a top plan view of a backing plate 28 constructed in accordance with the principles of the present invention and prior to being installed into a PECVD chamber as illustrated in FIGS. 1 and 2 and above described. The backing plate 28 as shown in FIG. 3 is however typical of the backing plate as illustrated in the PECVD chamber as illustrated in FIG. 2. The backing plate 28 includes a central opening 150 which is adapted to receive the process gas delivery assembly 104 as shown in FIG. 2. A plurality of openings 152 surround the opening 150 and the openings 152 are adapted to receive the threaded supports 108 as above described. Additional such openings 152 are disposed outwardly from the opening surrounding the opening 150 and also are adapted to receive threaded supports 108 thus providing additional distributed support for the diffuser 22.

A fluid conduit 154 having an input port 156 and an output port 158 is illustrated disposed in a serpentine or tortuous path along the top surface 160 of the backing plate 28. A source of fluid such as liquid or gas is attached to the input port 156 and appropriate pressure is supplied thereto either as a result of the pressurization of the source or by way of a pump or similar such apparatus to cause the fluid to circulate through the conduit 154 exiting the output port 158 and either returning to the fluid source, being exhausted to the atmosphere, or passing through a heat exchanger and ultimately return to the source depending upon the type of fluid being used. The passage of the fluid through the conduit 154 and over a substantial portion of the upper surface 160 of the backing plate 28 will remove excess heat generated by the sustained plasma in the processing area 80 of the PECVD chamber. The amount of excess heat removed will be such as to maintain the temperature of the substrate 14 at approximately 200° C.

One form which the conduit 154 may take is to provide a continuous groove in the upper surface 160 of the backing plate 28 which defines the desired path that the fluid is to take. After the groove is formed a tube, preferably continuous, may then be bent to conform to the path of the groove. The tube thus so formed is placed within the groove and a plurality of retaining plates or strips such as shown at 162 are disposed at discrete positions spaced along the length of the tube to retain it in position within the groove and in thermal transfer contact with the surface 160 of the backing plate 28.

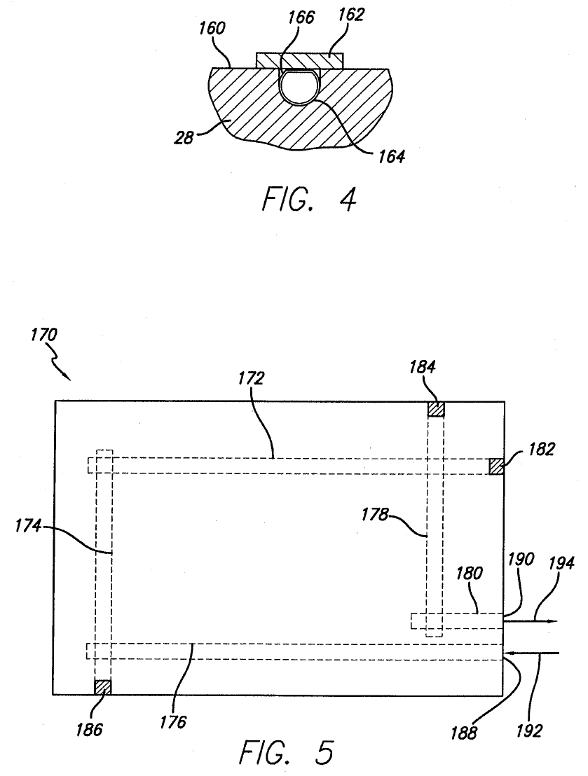

FIG. 4 shows the tube 164 disposed within the groove 166 and having a retaining plate 162 disposed over the top of the tube 164 and secured to the upper surface 160 of the backing plate 28. As illustrated in FIG. 4, the surface of the tube 164 is flattened by the retaining plate or strip 162 or preferably may be flattened before the plate 162 is assembled onto the surface 160 of the backing plate 28. The retaining plate 162 may be held in place on the surface 162 in any manner well known to the art such as by welding, screws, bolts or the like.

Referring now more particularly to FIG. 5, there is shown an alternative manner in which the fluid conduits may be formed in a backing plate. As is therein illustrated, a backing plate 170 includes a plurality of gun drilled bores 172 through 180 formed in the body of the backing plate 170. As is illustrated, the bore 172 intersects with the bores 174 and 178 and the bore 174 intersects with the bore 176 and the bore 178 intersects with the bore 180. The entry point of the bore 172 is plugged as shown at 182; the entry point of the bore 178 is plugged as shown at 184 while the entry point of the bore 174 is plugged as shown at 186. The entry point 188 for the bore 176 forms an inlet port while the entry point 190 of the bore 180 forms an outlet port for the thus continuous fluid conduit formed by the interconnected bores as above described. Although a single continuous gun drill fluid conduit formed by the bores is illustrated in FIG. 5 it should be understood that a plurality of parallel fluid conduits may be formed by gun drilling through the entire length or width of the backing plate 170 or alternatively, a plurality of other bores interconnecting the ones as illustrated in FIG. 5 may be formed to provide one or more serially connected fluid conduits which may form a continuous or a tortuous path through the body of the backing plate 170. As above described, fluid would be circulated by passing from a source (not shown in FIG. 5) into the input port 188 and out the outlet port 190 as illustrated by the arrows 192 and 194 to remove the excess heat generated by the sustained plasma within the processing area 80 of the PECVD chamber during the processing of a solar voltaic panel.

In accordance with another embodiment of the cooled backing plate constructed in accordance with the principles of the present invention, the plate 170 as shown in FIG. 5 may be a discrete plate of material apart from the backing plate 28. This discrete plate of material may have gun drilled bores as described in conjunction with FIG. 5 formed therein and may be interconnected to provide a continuous fluid conduit or may be a plurality of parallel conduits for conducting cooling fluid therethrough. Alternatively, the separate and discrete plate may have tubes disposed within grooves as above described in conjunction with FIGS. 3 and 4. In either event the separate and discrete plate may then be secured to the backing plate 28 by bolts, welding, screws or other fasteners as may be desired. The separate and discrete plate must be in thermal transfer contact with the backing plate to allow fluid circulated through the conduits to remove excess heat from the backing plate as above described. Alternatively, a plurality of such discrete plates may be formed and attached to the backing plate at preselected positions.

The fluid to be circulated through the conduits, whether through a tube or through gun drilled bores may be a gas or a liquid as above indicated. Preferably, if the fluid is a liquid, in accordance with a preferred embodiment, the liquid would be deionized water or alternatively, glycol. If the fluid to be circulated is a gas, then preferably, the gas would be dry air or alternatively nitrogen. Other liquids and gases may be utilized in accordance with the principles of the present invention so long as the liquid or gas is capable of removing the excess heat from the chamber to maintain the backing plate in a stable condition.

There has thus been described a PECVD chamber having a cooled backing plate adapted to remove unwanted heat generated within the chamber by the plasma during a sustained deposition process as required for the production of a solar voltaic panel, the excess heat is removed by passing a cooling fluid such as liquid or gas through an appropriate fluid conduit disposed in thermal transfer contact with a backing plate. While the foregoing is directed to embodiments of the present invention other and further embodiments of the invention may be devised without departing from the basic scope thereof and the scope thereof is determined by the claims that follow.

It has been found that under certain circumstances it is desirable to provide a thermal transfer path directly from the diffuser to the cooled backing plate constructed in accordance with the principals of the present invention.

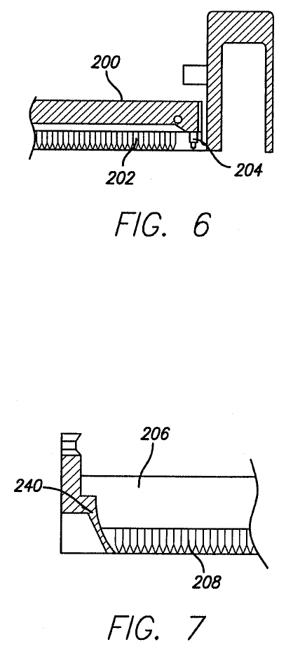

By referring now more particularly to FIG. 6 there is illustrated one embodiment of accomplishing such a thermal transfer path between the diffuser and the backing plate. As is therein shown, the backing plate 200 is directly bolted to the diffuser 202 as illustrated by the bolt 204 passing through the backing plate 200 and into the edge of the diffuser 202. The backing plate 200 will be constructed in the manner above described with respect to the embodiments in FIG. 3 or 5. The diffuser will be constructed and function in a manner as above described with regard to FIG. 1.

Referring now more particularly to FIG. 7, there is illustrated an alternative embodiment for providing a thermal transfer path between a diffuser and a cooled backing plate constructed in accordance with the principals of the present invention. As is therein shown, the backing plate 206 is connected to the diffuser 208 by a sheet metal skirt 240 which also creates a flexible/compliant connection to provide differential thermal expansion and contraction between the diffuser and the backing plate.

Through utilization of either of the alternative embodiments as shown in FIG. 6 and FIG. 7 the cooled backing plate constructed as above described and illustrated is capable of conducting excess heat generated by the plasma within the processing chamber away from the diffuser as well as the backing plate through the utilization of the cooling fluid which passes through fluid conduits formed within the backing plate.

What is claimed is:

1. In a plasma enhanced chemical vapor deposition chamber for depositing amorphous or microcrystalline silicon on a glass substrate to fabricate solar cells, the improvement comprising:
a backing plate carried by said chamber;
at least one fluid receiving conduit supported by said backing plate and receiving cooling fluid to remove heat generated within said chamber by said plasma; and
said conduit defining an input port for injecting said fluid into said conduit and an output port for removing said fluid from said conduit.

2. The improvement as defined in claim 1 wherein the flow of said cooling fluid through said conduit is sufficient to maintain the temperature of said substrate at approximately 200° C.

3. The improvement as defined in claim 1 which further includes a heat exchanger coupled to said conduit to reduce the temperature of said cooling fluid as it is circulated between said output and input ports.

4. The improvement as defined in claim 1 which further includes a thermal transfer contact between said diffuser and said backing plate.

5. The improvement as defined in claim 3 wherein said thermal transfer contact is provided by bolting said backing plate to said diffuser.

6. The improvement as defined in claim 3 wherein said thermal transfer contact is provided by a sheet metal skirt interconnected between said backing plate and said diffuser.

7. The improvement as defined in claim 1 wherein said backing plate includes a surface defining a groove therein and said conduit comprises a tube disposed within said groove and in thermal transfer contact with said backing plate.

8. The improvement as defined in claim 4 which further includes a retainer strip disposed over said tube and secured to said backing plate surface to secure said tube in said groove.

9. The improvement as defined in claim 5 wherein said groove defines a tortuous path and which further includes a plurality of retainer strips disposed spaced along said tube.

10. The improvement as defined in claim 6 wherein said tube is flattened along the mutual contact area with each said retainer strip.

11. The improvement as defined in claim 1 wherein said conduit is formed by producing openings through said backing plate.

12. The improvement as defined in claim 8 wherein said openings are provided by gun drilling.

13. The improvement as defined in claim 9 wherein at least some of said gun drilled conduits intersect to provide continuous conduits.

14. The improvement as defined in claim 10 wherein at least some openings in said backing plate formed during said gun drilling are plugged.

15. The improvement as defined in claim 1 wherein said cooling fluid is a liquid.

16. The improvement as defined in claim 12 wherein said liquid is deionized water.

17. The improvement as defined in claim 3 wherein said cooling fluid is a liquid.

18. The improvement as defined in claim 15 wherein said liquid is deionized water.

19. The improvement as defined in claim 1 wherein said cooling fluid is a gas.

20. The improvement as defined in claim 18 wherein said gas is clean dry air.

21. The improvement as defined in claim 18 wherein said gas is nitrogen.

22. The improvement as defined in claim 4 wherein said cooling fluid is a liquid.

23. The improvement as defined in claim 21 wherein said liquid is deionized water.

24. In a plasma enhanced chemical vapor deposition chamber for depositing amorphous or microcrystalline silicon on a glass substrate to fabricate solar cells, the improvement comprising:
a backing plate carried by said chamber;
a separate plate having at least one fluid receiving conduit;
means for affixing said separate plate to said backing plate in thermal transfer contact therewith;
said fluid receiving conduit receiving cooling fluid to remove heat generated within said chamber by said plasma; and
said conduit defining an input port for injecting said fluid into said conduit and an output port for removing said fluid from said conduit.

25. The improvement as defined in claim 24 wherein said cooling fluid is a liquid.
